(19) United States
(12) Patent Application Publication
(10) Pub. No.: US 2011/0111134 A1
(43) Pub. Date: May 12, 2011

(54) Systems and Methods of Preparation of Photovoltaic Films and Devices

(75) Inventor: Makarand P. Gore, Fort Collins, CO (US)

(73) Assignee: YewSavin, Inc., Fort Collins, CO (US)

(21) Appl. No.: 12/912,116

(22) Filed: Oct. 26, 2010

Related U.S. Application Data
(60) Provisional application No. 61/259,538, filed on Nov. 9, 2009.

(51) Int. Cl. B05D 3/06; B05C 9/08; B41F 33/00

(52) U.S. Cl. 427/555; 427/532; 427/558; 118/620; 118/641; 101/483

(57) ABSTRACT

Described herein are systems and methods for deposition of films using energy dispensers combined with film-material dispensers. The processes achieve high energy efficiency and speed by deposition of film materials that absorb energy in a designed radiation band, coupled with delivery of energy using a radiation source with a band matched to the absorbance band of the film deposition material. It is possible to use the energy for drying, fusion, chemical conversion, sintering of the deposited materials to produce films for visual, graphic or electronic applications. The process does not cause significant heating of substrates. The energy can be delivered to specified material deposition locations, thus using substantially less energy than bulk heating.

### CROSS REFERENCE

This application claims benefit of U.S. Provisional Application No. 61/259,538, entitled, Energy on Demand Processing Systems and Films Formed Thereof, filed Nov. 9, 2009, which is incorporated herein by reference in its entirety.

### TECHNICAL FIELD

The present invention is generally related to production of films, and more particularly related to production of films by printing.

### BACKGROUND

Application of fluids and conversion to solid films using processes such as drying by heat, or by physical transformations such as structural changes due to fusion, and chemical transformations such as polymerization or photo-thermal decomposition using radiation, is used in many coatings such as painting, electronics manufacture, printing, deposition by thermo-chemical change (e.g. MOVCD), and protective paints, and coatings. A particularly powerful and fast emerging technology is digital printing. The large scale digital printing is done by application of fluid in precise drops using piezo, thermal inkjet devices and liquid electro photography (LEP). In conventional presses, fluids are applied using offset, gravure, screen, flexographic, and dry toner electro photography (EP). Special inks that can be thermally converted to films with electronics properties are used in preparing conductors, or semiconductors as in case of MOVCD. These technologies are used for film deposition, printing, and manufacture of articles such as PCBs or printed electronics devices such as RFID, solar panels and displays. For example, a system used by FUJI/XEROX describes high power xenon lamps used in fusion of toners. The film formation is caused by energy, either by direct bulk or blackout heating of the chambers and towers, or by a complete swath of radiation across the media, heating major portions of the film and substrates.

### SUMMARY

Example embodiments of the present disclosure provide systems and methods of energy on demand processing of films. Briefly described, in architecture, one example embodiment of the system among others can be implemented as follows: a printing device configured to deposit film precursor in a pattern on a substrate, the film precursor having high absorbance for at least one band of radiation; and an irradiation device configured to deliver energy to the film precursor in at least one band of radiation.

Embodiments of the present disclosure can also be viewed as providing methods of energy on demand processing of films. In this regard, one embodiment in such a method, among others, can be broadly summarized by the following: depositing film precursor in a pattern, the film precursor having high absorbance for at least one band of radiation; and delivering radiation energy to the film precursor in the at least one band of radiation.

### BRIEF DESCRIPTION OF THE DRAWINGS

The invention is described in reference to several drawings to illustrate the embodiments.

FIG. 1 is a flow diagram of an example embodiment of a method of energy on demand processing of films.

FIG. 2 is a signal diagram of wavelengths of the absorber precursor and emission wavelength of the radiation source.

FIG. 3 is a system diagram of an example embodiment of an energy on demand (EOD) printing system.

FIG. 4 is a system diagram of an example embodiment of combined inkjet and light energy sources.

FIG. 5 is a system diagram of an example embodiment of inkjet deposition combined with rotating mirror optics for energy delivery.

FIG. 6 is a system diagram of an example embodiment of offset contact printing process, illustrated with three light delivery options.

### DETAILED DESCRIPTION

Embodiments of the present disclosure will be described more fully hereinafter with reference to the accompanying drawings in which like numerals represent like elements throughout the several figures, and in which example embodiments are shared. Embodiments of the claims may, however, be embodied in many different forms and should not be construed to be limited to the embodiments set forth herein. The examples set forth herein are non-limiting examples, and are merely examples among other possible examples. The term matched band is defined as the match between the absorption band of the precursors or films, and the emission band of the radiation source; which may have less than 100 nm difference in the wave lengths at full-width, half max band of absorption and emission spectrum.

There are examples of blackout pattern energy delivery (as in case of IR or xenon lamp) delivery, and there are examples of digital delivery of energy registering a pattern on a “full-bleed” black out of films (such as photolithography of circuits, and direct to plate processes). Extremely fast, precise and controlled deposition of films in the digital delivery methods in all methods described so far is followed by analog delivery of energy for drying, curing or setting the film precursors. There is a need for a very fast and high energy density delivery mechanism to the film precursors that are deposited by these techniques or printing methods. The energy in all methods described so far is delivered with primitive concept of “clothes line drying,” using radiation or ‘hot air currents.’ For example, the energy may be delivered to an entire surface under exposure, and in many cases the entire chamber using lamps and hot air currents, regardless of the fact that the film is only 1/100^{th} to 1/10^{th} of the mass requiring heating. Furthermore, the typical average coverage area in any printing is 50% of the total surface area. The energy needs for film formation processes (drying, fusing etc.) in modern devices is greater than 50% of the total energy required. With the acute environmental, energy and cost concerns, there is a severe unmet need to address the energy consumption. Table 1 provides example energy requirements of some digital presses.

TABLE 1
Printers and Drive Power

| | | Energy | |
|---|---|---|---|
| Digital Press | Manufactures | in KW | Drying Energy KW |
| Versamark VL4000 | KODAK | 48 | 32.6@50% |
| (Inkjet) | | | |
| Versamark VL2000 | KODAK | 40 | 32.6@50% |
| (Inkjet) | | | |
| Indigo 7000 (LEP) | HP | 18 | Not Specified >9 |
| | | | (Est.) |
| Colorstream 10000 | Oce | 50 | 46 |
| Xerox 480/890 | Xerox | 48 | Not specified |
| T300 Color Inkjet | HP | 109 | >80 (Estimate) |
| Web Press | | | |

There have been attempts to reduce energy used in fusing or drying. For example, Xerox engineers have developed a flash fusion using high powered xenon lamps, which is an analog process. As another example, MEGTEC has developed regenerative oxidizer dryers, that burn the ink/toner solvents used in printing to gain heat for drying. However, this is analog use of energy that does burn fuel, is costly and produces CO2. Apart from the energy costs, these systems suffer from other disadvantages. For example, inefficient delivery also requires long paths or tray delays and media deformation. The speed of drying also affects dot gain and ink mixing. Uncontrolled mixing of inks degrades print quality. This can be a major issue in the case of non-adsorbent media such as polymers, and lower quality media such as newsprint. Even in cases of adsorbent media, deposition of large quantity of ink may cause defects due to media deformation, image distortion due to mixing of inks at the borders (unintended bleeding of one color in other), and loss of dot definition due to excessive or too little spreading. In the case of dry toner electro photography (EP) or liquid electro photography (LEP), the fusing and drying speed may limit the printing speed, since the excessive energy application using current technologies can cause paper charring, and toner burns etc.

The systems and methods of energy on demand processing of films described herein provide an efficient form of delivery referred to as “Energy on Demand.” This disruptive process “specifically” delivers radiation energy “beam” to locations of films. In an example embodiment, only specific locations of the medium are covered by the film precursors. The film precursors have high absorption for a selected radiation band. “Specifically” delivered radiation energy may include any process where the deposition includes placing a high absorbance film precursor in a location, and at least the area location is exposed to energy by a raster controlled signal e.g. a pulse. This may be accomplished by activating a radiation source such as a high power LED, LASER diode or lamp focused on a small location defined by elements of the film covered area, such as by a bitmap.

In one example embodiment, the radiation source may be activated by an electronic signal synchronized with or in correlation to the electronic signal used to apply the film element, or a bitmap thereof. For example, the raster signal used to write a latent image of the print pattern in EP or LEP may be used to activate a radiation source to deliver energy to the area covered by toner on the media. In inkjet printing, the signals to nozzles or pens are used to activate the energy. In the case of lithography and offset printing, the digital images of images used to create lithographic plate are used to drive the energy delivery. In a functional system, the synchronized energy signal may have an optional time (td) delay in proportion to the travel time of the media from the application point to exposure point given by equation t_{d}=(d/s) where d=distance between application dot and energy and s=speed of the media.

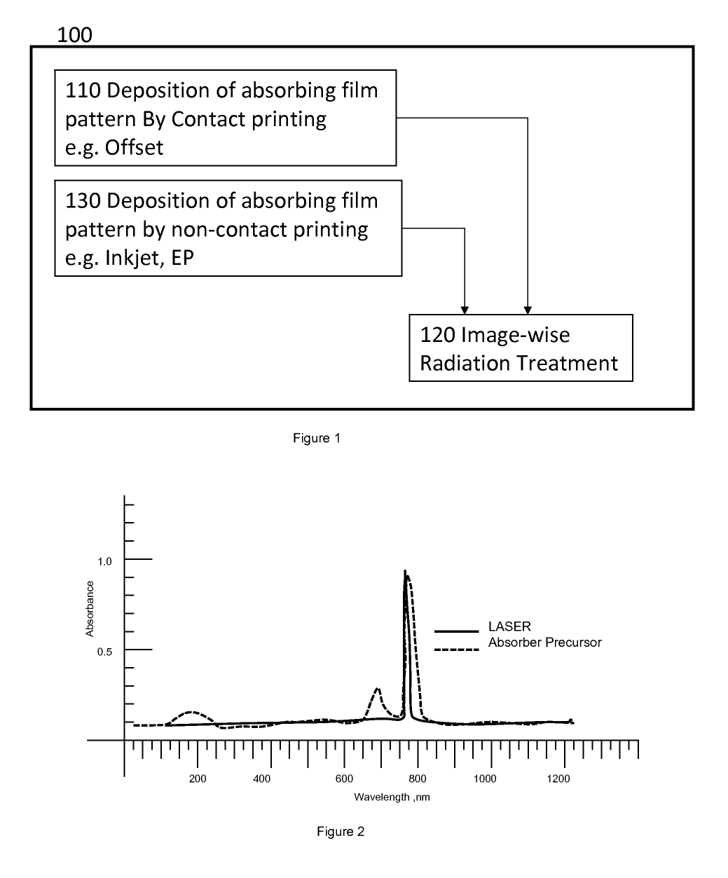

FIG. 1 provides flow diagram 100 of an exemplary embodiment of a method of energy on demand processing of films. In block 110, an image or a pattern of the film precursors is deposited on a substrate. A pattern may be described as the application of the precursors in any shape. Non-limiting examples of methods of application of the image or pattern are deposition systems used in slot coating, offset printing (lithography), screen printing and rotary screen printing, flexography, gravure and roto-gravure, powder delivery as in first step of thermo graphic printing, dry toner electro photography, liquid electro photography, thermal inkjet, piezo inkjet, and MEM jet printing, among others. Numerous examples of the inks and printing technologies are described in “The Printing Ink Manual”, Leach, R.; Pierce, R, Eds, Kluwer Academic Publishers, The Netherlands, 5^{th} edition 2004, ISBN 0-948905-81-6, which is entirely incorporated herein by reference.

In block 120, the film precursors are treated with an image-wise burst of radiation energy, a delivery of energy, in which the exposed areas are restricted to the area covered by the film precursors. In block 130, an alternative embodiment where the deposition process involves ‘flight’ of material from one location to another such as inkjet, MEMjet, dry toner EP and LEP, the particles travel through the energy beam of controlled intensity. The intensity of the beam may be adjusted according to the energy requirement of each of the materials and the effects thereof. A non-limiting example of delivery of energy may include implementing raster graphics or bitmap images to drive a beam reflected off a rotating mirror across the substrate, only exposing the electronic data deposited precursors to form a film. In an example embodiment using dry toner and LEP, the image files to drive the latent image on OPC may be used to synchronously drive an energy beam emanating from a source such as a LASER diode with appropriate delay introduced to allow for media travel. In an alternative embodiment a “process energy print bar” including an array of energy sources such as non-limiting examples of LEDs, LASER diodes, XENON lamps, and optical fiber arrays may be positioned across the path of media, and are activated by a latent image stored in the print driver memory.

In cases where the inkjet “print head” is scanned across the media to deposit films, the same signals used to fire the nozzles may be used to fire energy bursts from an attached LASER diode, or optical fiber attached to the body of the print head, with an added time delay for exact match of droplet and energy delivery. In case of the practice of the disclosed systems and methods of energy on demand processing of films where heating is the mechanism for film setting, the film precursors may absorb at least 20% of the radiation energy. In an example embodiment, the film precursors are configured to absorb 50% of the radiant energy. In an alternative embodiment, the film precursors may be configured to absorb 80% or more of the energy delivered by the source. For these configurations, the film precursors are have at least one absorption band that is matched to at least one band of the emission source and absorbs at least 50% of the radiation or Optical Density of 0.5 in precursor form. A matched band may have less than 100 nm difference in the wave lengths at full-width, half max band of absorption and emission spectrum.

FIG. 2 shows the matching of film absorption and source emission bands. In this particular example, a LASER is configured to emit energy at approximately 780 nm, to match the absorbance of the precursor. As the overlapping peaks show, the absorber spectrum of the precursors and the radiation wavelengths are ‘matched’. The film may have intrinsic absorption at the wavelengths of the radiation due to the film precursors, or an added absorber such as Indocyanine green for the example shown at the 780 nm band.

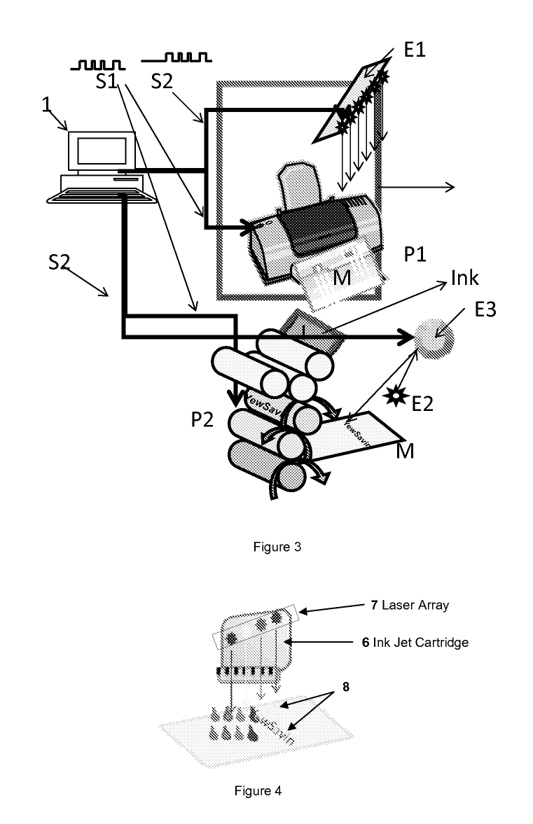

FIG. 3 shows the matching of energy to precursor absorbance as applied to offset printing, with a variety of light delivery systems. In one example design embodiment, computer 1 is connected to a print mechanism such as an inkjet printer P1 or an offset mechanism P2, and a light source E1, through electrical signal and power control cables S1 and S2. The inks of the inkjet or offset system may have high absorbance in the radiation band produced by sources E1 and E2. The process of EOD comprises the sending of signals for printing through S1; and sending a synchronous, asynchronous or a delay added signal to light sources E1 and E2. Signal S1 causes the deposition of high absorbance inks or film precursors on the media in the desired pattern, and signal S2 causes exposure of the locations of the deposited ink and film precursors. In cases where the position of deposition and exposure points are distant, an optional time delay corresponding to the exact time interval of travel between the deposition points to exposure point may be present in (raster) signal S1 and signal S2. An example embodiment of the process may include 1. sending signals to P1 or P2, and synchronous delayed, or asynchronous signals S2 for E\energy systems E1 and E2, and generating signals for the print device to apply ink “I” with matched absorber to the media; 2. printing the images on media M using electronic signals S1 as bitmap raster files, for example; and 3: exposing the ink to a “matched radiation” using signals S2, synchronously or asynchronously, with or without time delay.

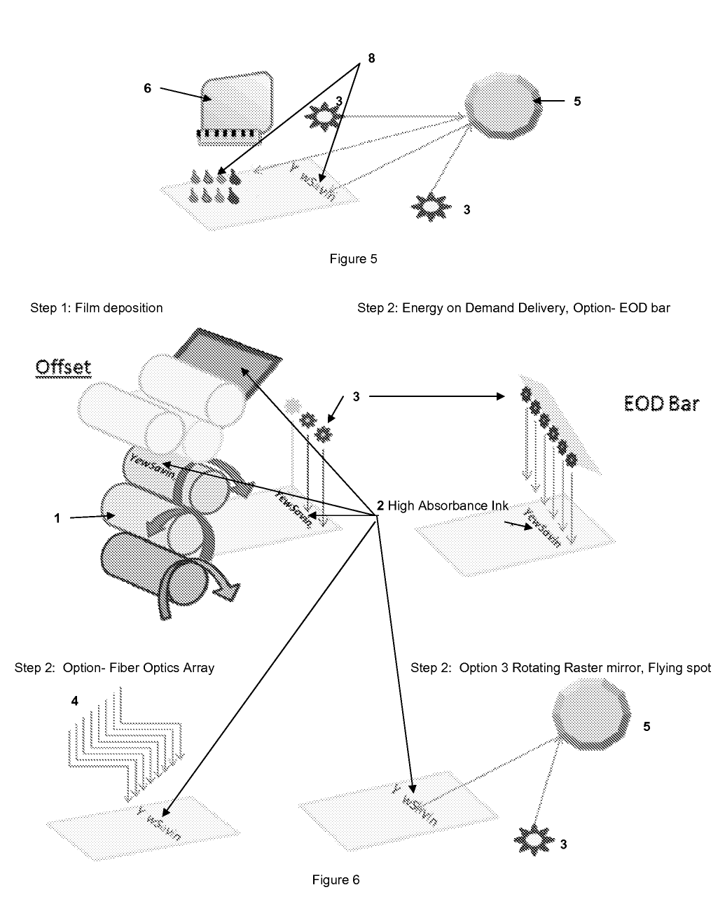

In some cases of non-contact printing methods, the disclosed systems and methods of energy on demand processing of films may be applied in two stage “in-flight” and “on surface” exposure to control not only drying or fusing, but the dot gain, optical density and solvent composition of the material applied to the substrate. Ink jet and liquid electro photography are examples of such cases. FIG. 4 shows one stage “with light and ink nozzles”, and FIG. 5 shows two stages, one “in flight” and one “on substrate” exposure using “flying spot” or rotating mirror raster print architecture for ink-jet printing. Ink jet cartridge 6 is fitted with LASER array 7. Ink jet or film precursor drops with high absorbance 8 are deposited on the media by cartridge 6, while simultaneously exposed to radiation from array 7, either in flight or upon deposition on the medium, causing processed films composed of drops or processed drops 8.

Various high speed commercial applications such as printing require that the absorbance requirements of the substrate do not affect the visual appearance of the ink films. In such cases, the maximum absorption band matched to source may be outside of visual absorption bands in the precursors. In case of the film precursors where drying occurs by polymerization such as UV inks, the absorption may be greatly reduced to at least 1%, more preferred 10% and most preferred >20% of the incident radiation. Due to recent advances in LED, LASER LED and lamp technologies, light sources in narrow wavelength band with high power density are available. The precursor or film absorbance parameters may be met due to intrinsic intended absorbance of the precursors or films, e.g. in case of printing inks For example, an ink with intense yellow color of optical density 1 absorbs 90% of blue waveband 400˜450 nm, an ink with magenta color of optical density 1 absorbs 90% of green waveband at 520˜620 nm, and the cyan color ink with optical density of 1 absorbs 90% of the red wave band at 640˜740 nm. In example embodiments, additives such as absorbers in UV, IR, and near-IR range may be added to the film to increase the absorbance in the selected regions matching with the radiation source.

Table 2 shows the film application/printing methods and the energy on demand options. A large number of architectures may be created using the combinations, although the table will result in 119 non-limiting example combinations of deposition and EOD engines.

TABLE 2
Deposition and EOD methods, combination
can result in 119 architectures

| Step 1, Deposition, Printing or | Step 2: EOD Image wise |
|---|---|
| Impression Method | Exposure Methods |
| Offset Lithography, Web or Sheet | X-Y galvo |
| Fed, WL offset | |
| Screen Printing, Rotary | Flying Spot- Rotating Mirror Raster |
| Screen Printing | |
| Flexography, Stack Press | Print Bar Modular Segment Array |
| Gravure (Rotogravure) | Fiber Optic Array |
| Platen Press | Print head attached die, or fiber array |
| Letter Press (Rotary and Sheet fed) | Print Bar LED or LASER array |
| Thermography | X-Y motion axis bars |
| Xerography | |
| Electro photography | |
| LASER Electro photography | |
| Dry toner | |
| Electro photography Liquid | |
| toner (LEP) | |
| Ionography | |
| Continuous Ink-Jet | |
| Piezoelectric Ink-jet | |
| Thermal Ink-jet | |
| Thermal Dye sublimation | |
| Thermal Wax Transfer | |
| Miscellaneous | In-Flight and on substrate (duel |
| | exposure) for non contact deposition |
| | and printing methods |

A large number of commercially available light sources may be used in practice of the disclosed systems and methods of energy on demand processing of films, e.g. fibers, bars, component LEDs. Table 3 shows a list of light sources in UV/VIS and NIR ranges as non-limiting examples. Table 3 shows a list of example light sources.

TABLE 3
Example light sources

| | | | Wavelengths | Source | | |
|---|---|---|---|---|---|---|
| Company | Part Number | Part Name | Choice | Dimensions | Power | |
| Northrop | ASM232C040 | GOLDEN | 790 to 980, | 9.6 cm × 0.25 cm | 40 | W CW |
| Grumman | | BULLET | with +/−3 | Bar | | |
| | | SUBMODULE | nm FWHM | | | |
| Northrop | ASM232P200 | GOLDEN | 790 to 980, | 9.6 cm × 0.25 cm | 200 | W QCW |
| Grumman | | BULLET | with +/−3 | Bar | | |
| | | SUBMODULE | nm FWHM | | | |
| Coherent | ONYX MCCP | 9010 Series HD | 808 nm, 915 nm, | 11 mm array | 2000 W to | |
| | 9010-HDPKG | array 1.6 mm | 940 nm, 975 nm | width, 1.6 mm pitch | 4500 W CW | |
| | | pitch | | Pump Array | | |
| Coherent | 532-8V or 532 | Prisma 532-V | 532 nm | 0.6 mm | 12 | W |
| | 14V | | | | | |
| SANYO | DL-7146-101S | Blue-Violet | 405 nm | 0.6 mm, down to | 85 | mw |
| | | Laser diode | | 300 nm collimated | | |
| SANYO | DL-3147-060 | Red Laser diode | 650 nm | 0.6 mm, down to 1 | 7 | mw |
| | | | | micron collimated | | |
| SHARP | GH04125A2A | Blue-Violet | 405 nm | 0.2 mm down to | 125 | mw |
| | | Laser diode | | 300 nm collimated | | |
| SONY | SLD433S4 | 60 W array Laser | 405 nm | 7.7 mm, 24° | 60 | W |
| | | diode | | Perpendicular and | | |
| | | | | 8° parallel | | |
| | | | | divergence | | |
| Nichia | NCSU034A | Surface mount | 385 nm | 2.1 mm | 330 | mw |
| | | UV LED | | | | |
| CryLas | FQCW 266 | DP/CW/SS | 266 nm | 0.6 mm | 70 | W |
| | | Laser | | | | |

| | | | | | |
|---|---|---|---|---|---|
| Omicron | LED MOD series | LEDMOD lab | 17 bands | Optical Fiber | 300 mw to |
| Laser | | series | between 255 nm | coupled, 1 mm or | 27 W |
| | | | to 950 nm | 2 mm diameter | |

The disclosed systems and methods of energy on demand processing of films offers greatly reduced energy costs, along with additional control parameters for print quality and media flexibility. Applications of this technology to a vast application such as printing may contribute to the green revolution.

FIG. 3 provides a system diagram for an example embodiment of a system configuration for the digitally controlled EOD system and processes. In one example design embodiment, computer 1 is connected to a print mechanism such as an inkjet printer P1 or an offset mechanism P2, and a light source E1, through electrical signal and power control cables S1 and S2. The inks I of the inkjet or offset system may have high absorbance in the radiation band produced by sources E1 and E2. The energy from source E2 is delivered with rotating mirror E3. The process of EOD comprises the sending of signals for printing through S1; and sending a synchronous, asynchronous or a delay added signal to light sources E1 and E2. Signal S1 causes the deposition of high absorbance inks I or film precursors I on the media M in the desired pattern, and signal S2 causes exposure of the locations of the deposited ink and film precursors. In cases where the position of deposition and exposure points are distant, an optional time delay corresponding to the exact time interval of travel between the deposition points to exposure point may be present in (raster) signal S1 and signal S2.

FIG. 4 provides a system diagram of an alternative embodiment of the disclosed systems of energy on demand processing of films in which the deposition and exposure modules are part of a single assembly. Ink jet cartridge 6 is fitted with LASER array 7. Ink jet or film precursor drops 8 with high absorbance are deposited on the media, while simultaneously exposed to radiation from array 7, either in flight or upon deposition on the medium.

FIG. 5 provides a system diagram of another embodiment of the disclosed systems of energy on demand processing of films, with an inkjet device 6 coupled to an offset light source 3, and a rotating mirror 5 delivering ‘flying spots’ of radiation energy on deposited locations. Inkjet cartridge 6 deposits ink or film precursor fluids 8 on the media with high absorbance corresponding to the radiation from light sources 3. Light sources 3 are activated under synchronous or delayed digital control by rotating mirror 5 to deliver energy pulses to precursors 8, causing the film formation.

FIG. 6 describes several combinations of the optical and printing systems in order to explain table 2, where a deposition technology is combined with a choice of energy delivery mechanism. Offset print mechanism 1 delivers ink or precursor fluids 2 to media. The offset deposition system is combined with light bar 3, rotating mirror 5, or an array of fibers 4. In an example embodiment, light bar 3 is positioned across media. The offset deposition system is combined with rotating mirror 5 receiving light from source 3, creating flying spots of energy across the deposited location of the media. An array of fibers 4 carrying light energy from a remote source is positioned across the media, exposing the high absorbance fluid deposited by the offset mechanism.

In a non-limiting example, high absorbance cyan ink are produced by addition of 0.5% indo-cyanine green to commercially available Epson cyan ink compatible with Espon Artisan 50 inkjet printer. The ink provides unaltered cyan color in human visual observation, and intense absorption peak at 780 nm band, which is invisible to humans.

In another example embodiment, a high absorbance magenta ink is produced by addition of 0.5% indo-cyanine green to commercially available Epson magenta ink compatible with Artisan 50 Ink Jet printer. The ink shows unaltered magenta color in human visual observation, and shows intense absorption peaks at the 780 nm band, which is invisible to humans.

In another example embodiment, an EOD system using commercially available Artisan 50 as an inkjet platform was built. A a non-limiting example of a commercially available Epson Artisan printer was modified by mounting, a LASER such as a non-limiting example of a Northrup-Grumman (Minnesota) 40 W 780 nm laser fitted with a cooling assembly and control integrated circuits, receiving signals from a computer and delivering the signals to the LASER and print cartridges. Inks as prepared in previous examples may be loaded in the ink cartridges, and the print mechanism may be activated with or without the laser. Prints of bars were deposited on HP glossy photo paper. The extent of the drying of inks may be determined by positioning HP inkjet color lock paper over the films and running a pressure roller at 1 and 2 seconds after the film has exited the printer. Table 4 shows results of the experiment with commercial and EOD inks, with both laser on and laser off.

TABLE 4
Experimental results for EOD system
test using EOD and commercial inks

| Experiment | Ink | LASER | % Ink Transfer |
|---|---|---|---|
| 1 | Commercial Cyan | OFF | >20% |
| 2 | Commercial Magenta | OFF | >20% |
| 3 | Commercial Cyan | ON | >20% |
| 4 | Commercial Magenta | ON | >20% |
| 5 | EOD Cyan | OFF | >20% |
| 6 | EOD Cyan | ON | 0% |
| 7 | EOD Magenta | OFF | >20% |
| 8 | EOD Magenta | ON | 0% |

Inks with high absorbance and LASER ON dry significantly faster due to significantly higher energy absorption.

Although the present invention has been described in detail, it should be understood that various changes, substitutions and alterations can be made thereto without departing from the spirit and scope of the invention as defined by the appended claims.

What is claimed is:

1. A method of processing films, comprising:
depositing film precursor in a pattern, the film precursor having high absorbance for at least one band of radiation; and
delivering radiation energy to the film precursor in the at least one band of radiation.

2. The method of claim 1, wherein the at least one band of the radiation is matched to the absorbance of the film precursor.

3. The method of claim 1, wherein the film precursor has an absorbance of at least 20% in the at least on radiation band.

4. The method of claim 1, wherein the radiation energy is delivered by at least one of:
a diode or LASER diode;
an ultraviolet diode or lamp;
an optical fiber; and
a bar with multiple rows of radiation sources.

5. The method of claim 1, wherein the film precursor is deposited by at least one of:
offset lithography;
web or sheet feed;
waterless offset;
screen printing;
rotary screen printing;
flexography;
stack press;
gravure or rotogravure;
platen press;
letter press;
thermography;
xerography;
electrophotography;
LASER Electro photography;
dry toner;
electro photography liquid toner (LEP);
iconography;
continuous ink-jet;
piezoelectric ink-jet;
thermal ink-jet;
thermal dye sublimation; and
thermal wax transfer.

6. The method of claim 1, wherein radiation energy is delivered by at least one of:
X-Y galvo;
flying spot;
rotating mirror raster;
print bar modular segment array;
fiber optic array;
print head attached die;
fiber array attached to print head;
print bar LED; and
LASER element array.

7. The method of claim 1, wherein the radiation energy is controlled and activated either synchronously by a digital printer input, or by a separate computer input.

8. The method of claim 1, wherein radiation energy is controlled and activated asynchronously.

9. A system of processing films, comprising:
a printing device configured to deposit film precursor in a pattern on a substrate, the film precursor having high absorbance for at least one band of radiation; and
an irradiation device configured to deliver energy to the film precursor in at least one band of radiation.

10. The system of claim 9, wherein the absorbance of the film precursor is matched to at least one wavelength band of the radiation.

11. The system of claim 9, wherein the film precursor has an absorbance of at least 10% in the at least on radiation band.

12. The system of claim 9, wherein the radiation energy is delivered by at least one of:
a diode or LASER diode;
an ultraviolet diode or lamp;
an optical fiber; and
a bar with multiple rows of radiation sources.

13. The system of claim 9, wherein the film precursor is deposited by at least one of:
offset lithography;
web or sheet feed;
waterless offset;
screen printing;
rotary screen printing;
flexography;
stack press;
gravure or rotogravure;
platen press;
letter press;
thermography;
xerography;
electrophotography;
LASER Electro photography;
dry toner;
electro photography liquid toner (LEP);
iconography;
continuous ink-jet;
piezoelectric ink-jet;
thermal ink-jet;
thermal dye sublimation; and
thermal wax transfer.

14. The system of claim 9, wherein radiation energy is delivered by at least one of:
X-Y galvo;
flying spot;
rotating mirror raster;
print bar modular segment array;
fiber optic array;
print head attached die;
fiber array attached to print head;
print bar LED; and
LASER element array.

15. The system of claim 9, wherein the radiation energy is controlled and activated either synchronously by a digital printer input, or by a separate computer input.

16. The system of claim 9, wherein radiation energy is controlled and activated asynchronously.

17. A system for processing films, comprising:
means for depositing film precursor in a pattern, the film precursor having high absorbance for at least one band of radiation; and
means for delivering radiation energy to the film precursor in the at least one band of radiation.

18. The system of claim 17, wherein the absorbance of the film precursor is matched to at least one wavelength band of the radiation.

19. The system of claim 17, wherein the film precursor has an absorbance of at least 10% in the at least one radiation band.

20. The system of claim 17, wherein the radiation energy is controlled and activated either synchronously by a digital printer input, or by a separate computer input; or asynchronously.
